(19) United States
(12) Patent Application Publication
(10) Pub. No.: US 2026/0068323 A1
(43) Pub. Date: Mar. 5, 2026

(54) Monolithic 3D Integrated Multi-Tier Circuits Utilizing 2D Semiconductors

(71) Applicant: Xuejun Xie, Palo Alto, CA (US)

(72) Inventor: Xuejun Xie, Palo Alto, CA (US)

(73) Assignee: PhantaField Inc., Palo Alto, CA (US)

(21) Appl. No.: 19/087,475

(22) Filed: Mar. 22, 2025

Related U.S. Application Data
(60) Provisional application No. 63/570,807, filed on Mar. 28, 2024.

(51) Int. Cl. H10D 88/00; H01L 23/522; H01L 23/528; H10D 30/47; H10D 62/80

(52) U.S. Cl. CPC H10D 88/00; H10D 30/481; H10D 62/883

(57) ABSTRACT

The present invention relates to the field of semiconductor devices, specifically addressing challenges in interconnectivity and transistor density. This patent describes a novel method utilizing 2D semiconductors for the creation of monolithic 3D integrated multi-tier circuits on top of an integrated circuit. The invention achieves substantially higher vertical interconnect bandwidth, significantly increased IO density, and orders of magnitude lower signal transmission delay compared to conventional methods like through-silicon via (TSV) or copper-to-copper hybrid bonding. These advancements are made possible by stacking integrated circuit layers monolithically, connecting layers with vias, and utilizing 2D semiconductor-based transistors. Furthermore, the invention allows for a substantial increase in transistor density, contributing to enhanced processing capability. The utilization of more cost-effective process nodes further enhances the economic viability of the invention.

### BACKGROUND OF THE INVENTION

Semiconductor devices, such as SRAM and DRAM circuits, are essential components in modern electronic systems. Traditional integration methods face challenges in achieving high vertical interconnect bandwidth, IO density, and transistor density. This invention leverages 2D semiconductors and a multi-layered 3D integration approach on an integrated circuit to address these challenges.

### BRIEF SUMMARY OF THE INVENTION

The invention involves the integration of 2D semiconductors to create monolithic 3D integrated multi-tier circuits (101) on a very large-scale integrated (VLSI) circuit (102), such as a GPU or CPU. Each tier (101) is fabricated with 2D semiconductor-based transistors (204), providing a scalable platform for high-performance computing. The multi-layered 3D integration enables high vertical interconnect bandwidth, IO density, and transistor density, making it suitable for a wide range of applications.

### BRIEF DESCRIPTION OF DRAWINGS

FIG. 1: Shows the overall architecture of the 3D integrated circuit (101) on top of the bottom integrated circuit (102) on a substrate (103).

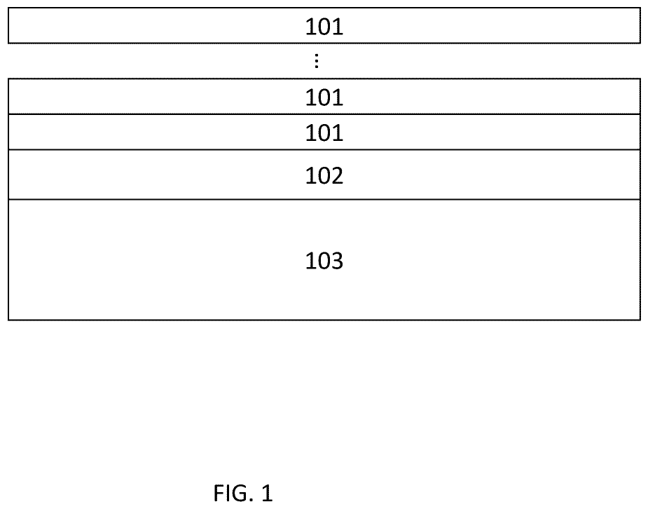

FIG. 2: Illustrates a detailed cross-section of the 3D integrated circuit tier (101), for example, an SRAM module, with a 2D semiconductor as the transistor channel (203).

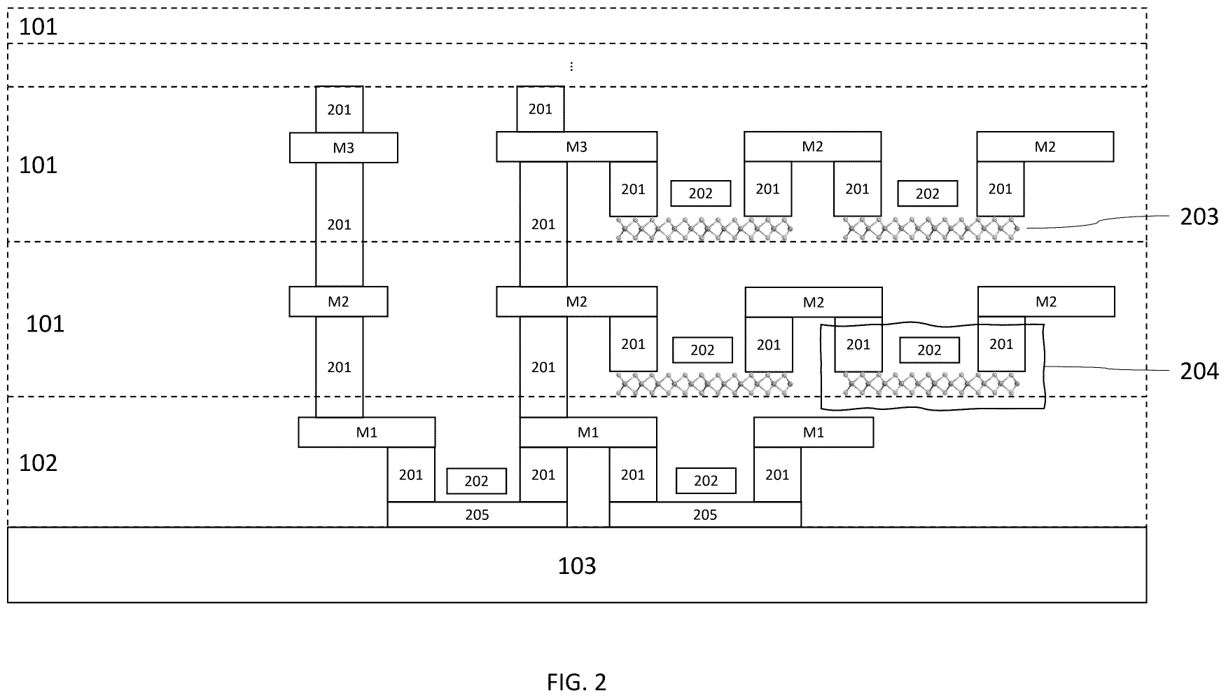

FIG. 3: Demonstrates one configuration of 3D stacked DRAM with a gate capacitor as the storage capacitor.

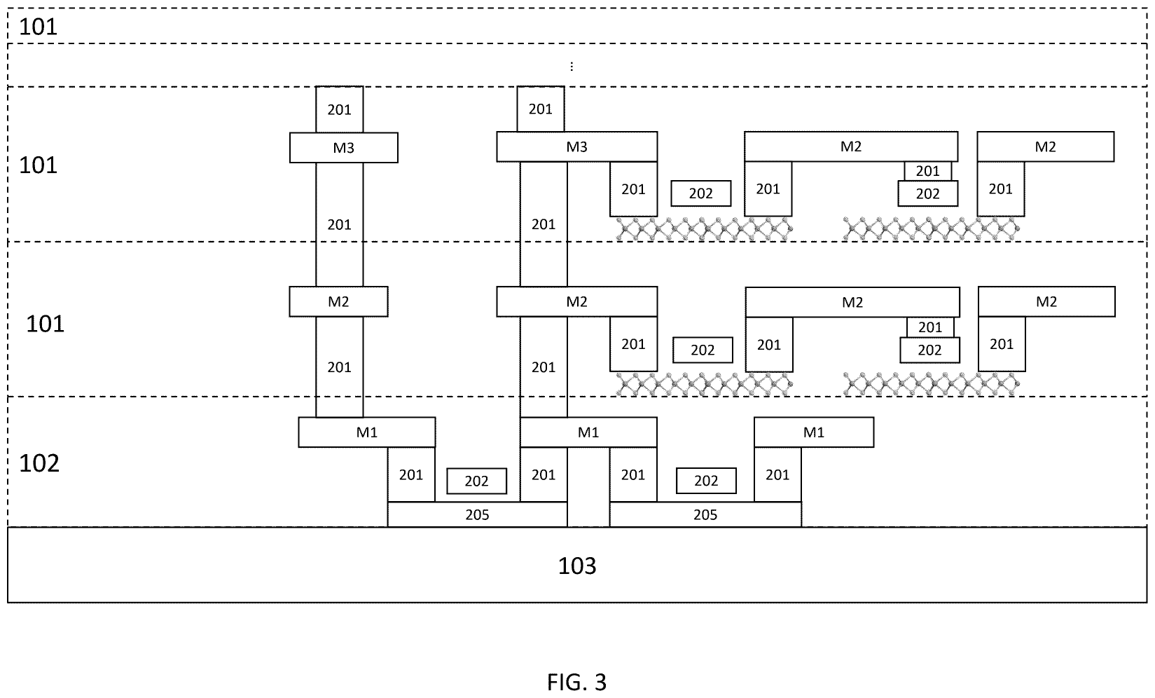

FIG. 4: Demonstrates one configuration of 3D stacked DRAM with a metal-insulator-metal (MIM) capacitor as the storage capacitor.

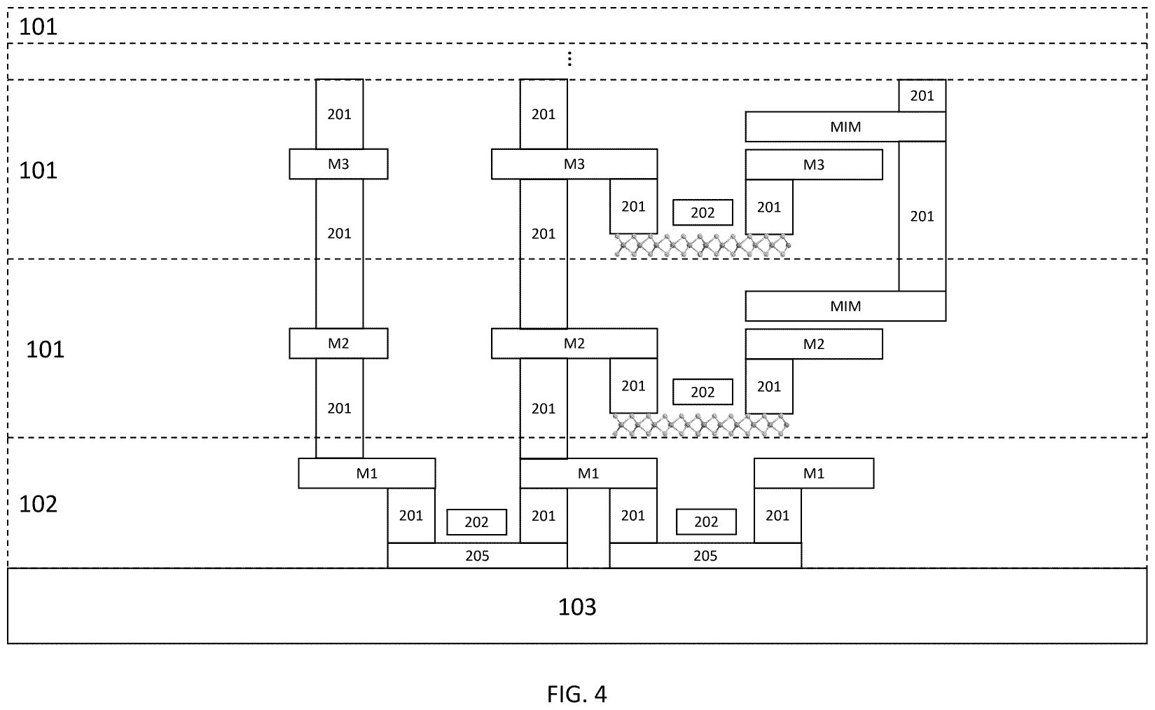

### DETAILED DESCRIPTION OF THE INVENTION

The present invention describes a method for fabricating a monolithic 3D integrated multi-tier circuit utilizing 2D semiconductors. The structure is composed of multiple vertically stacked integrated circuit tiers (101) built upon a base integrated circuit (102) on a substrate (103). The stacking process is achieved through lithography and deposition techniques, ensuring high interconnect density and optimal device performance.

### Fabrication Process

1. Base Layer Formation: The transistors (205) and integrated circuit (102) fabricated using any applicable semiconductor process on a substrate (103). This base layer may contain logic circuits, memory controllers, or processing units.
2. 2D Semiconductor Deposition: A thin film of a 2D semiconductor material, such as not limited to MoS₂, MoSe₂, WS₂, or WSe₂ (or black phosphorus, silicene, and other 2D materials) is deposited onto the base circuit using metal-organic chemical vapor deposition (MOCVD), molecular beam epitaxy (MBE), or atomic layer deposition (ALD). This layer serves as the active channel material for transistors in the subsequent tiers.
3. Fabrication of 3D Integrated Tiers (101): Each additional tier is constructed sequentially atop the existing structure. The fabrication includes:
   Patterning and deposition of transistors (203) using the 2D semiconductor material.
   Formation of gate structures (202) with high-k dielectrics and metal gate materials.
   Interlayer dielectric deposition to isolate the tiers electrically.
4. High-Density Via Interconnects (201): Vertical vias are etched and metallized to establish electrical connections between different tiers. These vias enable high IO density and efficient signal transmission.
5. Metal Interconnect Layers: Multiple metallization layers (M1, M2, M3) are patterned using damascene or subtractive etching techniques to form robust electrical connections between transistors and circuit elements within and across tiers.
6. Formation of device elements in different tiers such as random-access memory (SRAM), dynamic random-access memory (DRAM), Magnetoresistive random-access memory (MRAM), or Resistive random-access memory (RRAM),

### Structural Advantages

Enhanced IO Density: The high-density via (201) interconnections provide a significantly larger number of input/output connections than traditional TSV or Cu—Cu hybrid bonding.
Reduced Signal Delay: The vertical stacking minimizes interconnect length, reducing transmission delay and power consumption.
Increased Transistor Density: By utilizing multiple tiers, the effective transistor density is significantly increased, allowing for higher computational power and memory capacity.
Cost-Effective Scaling: The use of monolithic integration and 2D materials enables cost-effective scaling, achieving high performance without requiring ultra-fine process nodes.

1. A semiconductor device comprising an integrated circuit (102) and multi-tier integrated circuits (101) monolithically integrated using 2D semiconductors (203).

2. The semiconductor device of claim 1, wherein the integrated circuits (102) include, but are not limited to, processing units, memory controllers, and configurable logic arrays, encompassing graphics processing units (GPUs), central processing units (CPUs), digital signal processors (DSPs), memory controllers, field-programmable gate arrays (FPGAs), and application-specific integrated circuits (ASICs), fabricated using any applicable semiconductor process on a substrate (103).

3. The semiconductor device of claim 1, wherein the additional tiers of integrated circuits (101) are monolithically integrated atop the base layer of integrated circuits (102), interconnected by high-density vias (201) fabricated by lithography and metallization processes or damascene processes.

4. The semiconductor device of claim 1, wherein the two-dimensional semiconductors (203) are deposited through various thin-film deposition methods, including but not limited to metal-organic chemical vapor deposition (MOCVD), molecular beam epitaxy (MBE), or atomic layer deposition (ALD). The materials encompass a wide range of two-dimensional semiconductors, including transition metal dichalcogenides (e.g., MoS₂, MoSe₂, WS₂, or WSe₂), black phosphorus, silicene, and other 2D materials.

5. The semiconductor device of claim 1, wherein the additional tiers of integrated circuits (101) encompass a diverse range of circuit types, including but not limited to static random-access memory (SRAM), dynamic random-access memory (DRAM), Magnetoresistive random-access memory (MRAM), Resistive random-access memory (RRAM), logic circuits, analog circuits, mixed-signal circuits, light-emitting diodes (LEDs), photodiodes, and biosensors offering a wide spectrum of functionality and application.
